(19) United States
(12) Patent Application Publication
(10) Pub. No.: US 2024/0282014 A1
(43) Pub. Date: Aug. 22, 2024

(54) Attention-Based Method for Deep Point Cloud Compression

(71) Applicant: HUAWEI TECHNOLOGIES CO., LTD., Shenzhen (CN)

(72) Inventors: Kirill Sergeevich Mityagin, Moscow (RU); Roman Igorevich Chernyak, Moscow (RU); Chenxi Tu, Shenzhen (CN)

(21) Appl. No.: 18/637,212

(22) Filed: Apr. 16, 2024

Related U.S. Application Data
(63) Continuation of application No. PCT/RU2021/000442, filed on Oct. 19, 2021.

(51) Int. Cl. G06T 9/00; G06T 9/40

(52) U.S. Cl. CPC G06T 9/002; G06T 9/40

(57) ABSTRACT

Methods and apparatuses are provided for entropy encoding and decoding data of a three-dimensional point cloud, which includes for a current node in an N-ary tree-structure representing the three-dimensional point cloud, extracting features of a set of the neighboring nodes of the current node by applying a neural network including an attention layer. Probabilities of information associated with the current node is estimated based on the extracted features. The information associated with the current node is entropy encoded based on the estimated probabilities.

### CROSS-REFERENCE TO RELATED APPLICATIONS

This application is a continuation of International Application No. PCT/RU2021/000442, filed on Oct. 19, 2021, the disclosure of which is hereby incorporated by reference in its entirety.

### TECHNICAL FIELD

Embodiments of the present disclosure relate to the field of artificial intelligence (AI)-based point cloud compression technologies, and in particular, to entropy modelling using an attention layer within a neural network.

### BACKGROUND

Point cloud compression (PCC) has been used in a wide range of applications. For example, three-dimensional sensors produce a large amount of three-dimensional point cloud data. Some exemplary applications for three-dimensional point cloud data include emerging immersive media services, which are capable of representing omnidirectional videos and three-dimensional point clouds, enabling a personalized viewing perspective of and real-time full interaction with a realistic scene or a synthesis of a virtual scene.

Another important area of application for the PCC is robotic perception. Robots often utilize a plethora of different sensors to perceive and interact with the world. In particular, three-dimensional sensors such as Light detection and ranging (LiDAR) sensors and structured light cameras have proven to be crucial for many types of robots, such as self-driving cars, indoor rovers, robot arms, and drones, thanks to their ability to accurately capture the three-dimensional (3D) geometry of a scene.

Regarding practical implementation, bandwidth requirements to transfer three-dimensional data over a network and storage space requirements demand to compress point clouds up to a maximum level and minimize memory requirements without disturbing the entire structure of objects or scenes.

Geometry-based point cloud compression (G-PCC) encodes point clouds in their native form using three-dimensional data structures. In recent years, deep learning is gaining popularity in the point cloud encoding and decoding. For deep point cloud compression (DPPC), deep neural networks have been employed to improve entropy estimation.

### SUMMARY

The embodiments of the present disclosure provide apparatuses and methods for attention-based estimation of probabilities for the entropy encoding and decoding of a point cloud.

According to an embodiment, a method is provided for entropy encoding data of a three-dimensional point cloud, comprising: for a current node in an N-ary tree-structure representing the three-dimensional point cloud: obtaining a set of neighboring nodes of the current node; extracting features of the set of said neighboring nodes by applying a neural network including an attention layer; estimating probabilities of information associated with the current node based on the extracted features; entropy encoding the information associated with the current node based on the estimated probabilities.

The attention mechanism adaptively weights the importance of features of the neighboring nodes. Thus, the performance of the entropy estimation is improved by including processed information of neighboring nodes.

In an exemplary implementation, the extraction of features uses relative positional information of a neighboring node and the current node within the three-dimensional point cloud as an input.

The positional encodings may enable the attention layer to utilize the spatial position within the tree-dimensional point cloud. Thus, the attention layer may focus on improved information from features of neighboring nodes for better entropy modelling.

For example, the processing by the neural network comprises: for each neighboring node within the set of neighboring nodes, applying a first neural subnetwork to the relative positional information of the respective neighboring node and the current node; providing the obtained output for each neighboring node as an input to the attention layer.

Obtaining the relative positional information by applying a first neural subnetwork may provide features of the positional information to the attention layer and improve the positional encoding.

In an exemplary implementation, an input to the first neural subnetwork includes a level of the current node within the N-ary tree.

Using the depth within the tree as an additional input dimension may further improve the positional encoding features.

For example, the processing by the neural network comprises applying a second neural subnetwork to output a context embedding into a subsequent layer within the neural network.

Processing the input of the neural network to extract the context embeddings may enable a focus of the attention layer on independent deep features of the input.

In an exemplary implementation, the extracting features of the set of neighboring nodes includes selecting a subset of nodes from said set; and information corresponding to nodes within said subset is provided as an input to a subsequent layer within the neural network.

Selecting a subset of nodes may reduce the processing amount as the input matrix size to the attention layer may be reduced.

For example, the selecting of the subset of nodes is performed by a k-nearest neighbor algorithm.

Using features corresponding to k spatially neighboring nodes as input to the attention layer reduces the processing amount without a significant loss of information.

In an exemplary implementation, the input to the neural network includes context information of the set of neighboring nodes, the context information for a node including one or more of location of said node, octant information, depth in the N-ary tree, occupancy code of a respective parent node, and an occupancy pattern of a subset of nodes spatially neighboring said node.

Each combination of this set of context information may improve the processed neighboring information to be obtained from the attention layer, thus improving the entropy estimation.

For example, the attention layer in the neural network is a self-attention layer.

Applying a self-attention layer may reduce computational complexity as the set of input vectors is obtained from the same input, e.g. context embeddings combined with positional encodings.

In an exemplary implementation, the attention layer in the neural network is a multi-head attention layer.

A multi-head attention layer may improve the estimation of probabilities by processing different representations of the input in parallel and thus providing more projections and attention computations, which corresponds to various perspectives of the same input.

For example, the information associated with a node indicates the occupancy code of said node.

An occupancy code of a node provides an efficient representation of the occupancy states of the respective child nodes thus enabling a more efficient processing of the information corresponding to the node.

In an exemplary implementation, the neural network includes a third neural subnetwork, the third neural subnetwork performing the estimating of probabilities of information associated with the current node based on the extracted features as an output of the attention layer.

The neural subnetwork may process the features outputted by the attention layer, i.e. aggregated neighboring information, to provide probabilities for the symbols used in the encoding and thus enabling an efficient encoding and/or decoding.

For example, the third neural subnetwork comprises applying of a softmax layer and obtaining the estimated probabilities as an output of the softmax layer.

By applying a softmax layer, each component of the output will be in the interval [0,1] and the components will add up to 1. Thus, a softmax layer may provide an efficient implementation to interpret the components as probabilities in a probability distribution.

In an exemplary implementation, the third neural subnetwork performs the estimating of probabilities of information associated with the current node based on the context embedding related to the current node.

Such a residual connection may prevent vanishing gradient problems during the training phase. The combination of an independent contextual embedding and aggregated neighboring information may result in an enhanced estimation of probabilities.

For example, at least one of the first neural subnetwork, the second neural subnetwork and the third neural subnetwork contains a multilayer perceptron.

A multilayer perceptron may provide an efficient (linear) implementation of a neural network.

According to an embodiment, a method is provided for entropy decoding data of a three-dimensional point cloud, comprising: for a current node in an N-ary tree-structure representing the three-dimensional point cloud: obtaining a set of neighboring nodes of the current node; extracting features of the set of said neighboring nodes by applying a neural network including an attention layer; estimating probabilities of information associated with the current node based on the extracted features; entropy decoding the information associated with the current node based on the estimated probabilities.

The attention mechanism adaptively weights the importance of features of the neighboring nodes. Thus, the performance of the entropy estimation is improved by including processed information of neighboring nodes.

In an exemplary implementation, the extraction of features uses relative positional information of a neighboring node and the current node within the three-dimensional point cloud as an input.

The positional encodings may enable the attention layer to utilize the spatial position within the tree-dimensional point cloud. Thus, the attention layer may focus on improved information from features of neighboring nodes for better entropy modelling.

For example, the processing by the neural network comprises: for each neighboring node within the set of neighboring nodes, applying a first neural subnetwork to the relative positional information of the respective neighboring node and the current node; providing the obtained output for each neighboring node as an input to the attention layer.

Obtaining the relative positional information by applying a first neural subnetwork may provide features of the positional information to the attention layer and improve the positional encoding.

In an exemplary implementation, an input to the first neural subnetwork includes a level of the current node within the N-ary tree.

Using the depth within the tree as an additional input dimension may further improve the positional encoding features.

For example, the processing by the neural network comprises applying a second neural subnetwork to output a context embedding into a subsequent layer within the neural network.

Processing the input of the neural network to extract the context embeddings may enable a focus of the attention layer on independent deep features of the input.

In an exemplary implementation, the extracting features of the set of neighboring nodes includes selecting a subset of nodes from said set; and information corresponding to nodes within said subset is provided as an input to a subsequent layer within the neural network.

Selecting a subset of nodes may reduce the processing amount as the input matrix size to the attention layer may be reduced.

For example, the selecting of the subset of nodes is performed by a k-nearest neighbor algorithm.

Using features corresponding to k spatially neighboring nodes as input to the attention layer reduces the processing amount without a significant loss of information.

In an exemplary implementation, the input to the neural network includes context information of the set of neighboring nodes, the context information for a node including one or more of location of said node, octant information, depth in the N-ary tree, occupancy code of a respective parent node, and an occupancy pattern of a subset of nodes spatially neighboring said node.

Each combination of this set of context information may improve the processed neighboring information to be obtained from the attention layer, thus improving the entropy estimation.

For example, the attention layer in the neural network is a self-attention layer.

Applying a self-attention layer may reduce computational complexity as the set of input vectors is obtained from the same input, e.g. context embeddings combined with positional encodings.

In an exemplary implementation, the attention layer in the neural network is a multi-head attention layer.

A multi-head attention layer may improve the estimation of probabilities by processing different representations of the input in parallel and thus providing more projections and attention computations, which corresponds to various perspectives of the same input.

For example, the information associated with a node indicates the occupancy code of said node.

An occupancy code of a node provides an efficient representation of the occupancy states of the respective child nodes thus enabling a more efficient processing of the information corresponding to the node.

In an exemplary implementation, the neural network includes a third neural subnetwork, the third neural subnetwork performing the estimating of probabilities of information associated with the current node based on the extracted features as an output of the attention layer.

The neural subnetwork may process the features outputted by the attention layer, i.e. aggregated neighboring information, to provide probabilities for the symbols used in the encoding and thus enabling an efficient encoding and/or decoding.

For example, the third neural subnetwork comprises applying of a softmax layer and obtaining the estimated probabilities as an output of the softmax layer.

By applying a softmax layer, each component of the output will be in the interval [0,1] and the components will add up to 1. Thus, a softmax layer may provide an efficient implementation to interpret the components as probabilities in a probability distribution.

In an exemplary implementation, the third neural subnetwork performs the estimating of probabilities of information associated with the current node based on the context embedding related to the current node.

Such a residual connection may prevent vanishing gradient problems during the training phase. The combination of an independent contextual embedding and aggregated neighboring information may result in an enhanced estimation of probabilities.

For example, at least one of the first neural subnetwork, the second neural subnetwork and the third neural subnetwork contains a multilayer perceptron.

A multilayer perceptron may provide an efficient (linear) implementation of a neural network.

In an exemplary implementation, a computer program stored on a non-transitory medium and including code instructions, which, when executed on one or more processors, cause the one or more processors to execute steps of the method according to any of the methods described above.

According to an embodiment, an apparatus is provided for entropy encoding data of a three-dimensional point cloud, comprising: processing circuitry configured to: for a current node in an N-ary tree-structure representing the three-dimensional point cloud: obtain a set of neighboring nodes of the current node; extract features of the set of said neighboring nodes by applying a neural network including an attention layer; estimate probabilities of information associated with the current node based on the extracted features; entropy encode the information associated with the current node based on the estimated probabilities.

According to an embodiment, an apparatus is provided for entropy decoding data of a three-dimensional point cloud, comprising: processing circuitry configured to: for a current node in an N-ary tree-structure representing the three-dimensional point cloud: obtain a set of neighboring nodes of the current node; extract features of the set of said neighboring nodes by applying a neural network including an attention layer; estimate probabilities of information associated with the current node based on the extracted features; entropy decode the information associated with the current node based on the estimated probabilities.

The apparatuses provide the advantages of the methods described above.

Embodiments of the present disclosure can be implemented in hardware (HW) and/or software (SW) or in any combination thereof. Moreover, HW-based implementations may be combined with SW-based implementations.

Details of one or more embodiments are set forth in the accompanying drawings and the description below. Other features, objects, and advantages will be apparent from the description, drawings, and claims.

### BRIEF DESCRIPTION OF THE DRAWINGS

In the following, embodiments of the present disclosure are described in more detail with reference to the attached figures and drawings, in which:

FIG. 1a is a schematic drawing illustrating examples for the partitioning corresponding to a quadtree;

FIG. 1b is a schematic drawing illustrating examples for the partitioning corresponding to a binary tree;

FIG. 2a illustrates exemplarily the partitioning of an octree;

FIG. 2b shows an exemplary partitioning of an octree and the corresponding occupancy codes;

FIG. 3 is a schematic drawing illustrating the encoding and decoding process of a point cloud;

FIG. 4 shows an exemplary multi-layer perceptron;

FIG. 5 is a schematic drawing illustrating a recurrent neural network;

FIG. 6 illustrates exemplarily a long short term memory (LSTM) repeating module;

FIG. 7 illustrates exemplarily an attention mechanism;

FIG. 8 is a schematic drawing illustrating a transformer encoder network;

FIG. 9 is an exemplary flowchart illustrating a self-attention layer;

FIG. 10a is a schematic drawing illustrating an attention network;

FIG. 10b is a schematic drawing illustrating a multi-head attention network;

FIG. 11 shows an exemplarily the application of a convolutional filter and an attention vector;

FIG. 12 is a schematic drawing illustrating the layer-by-layer encoding/decoding process of an octree;

FIG. 13 is an exemplary flowchart illustrating the attention-based feature extraction;

FIG. 14 is an exemplary flowchart illustrating the attention-based feature extraction for a single node;

FIG. 15 illustrates exemplarily a tree-adaptive relative positional encoding;

FIG. 16 illustrates exemplarily a selection of k neighboring nodes;

FIG. 17 is a schematic drawing illustrating the combination of the context embedding and the positional encoding;

FIG. 18 shows exemplarily the depth of a node in the N-ary tree as an input to the positional encoding;

FIG. 19 is a schematic drawing illustrating the dimensions of the input and the output of the selection of a subset of nodes;

FIG. 20 illustrates exemplarily configurations of spatially neighboring nodes;

FIG. 21 is an exemplary flowchart of the encoding of a three-dimensional point cloud represented by an N-ary tree;

FIG. 22 is an exemplary flowchart of the decoding of a three-dimensional point cloud represented by an N-ary tree;

FIG. 23 is a block diagram showing an example of a point cloud coding system configured to implement embodiments of the present disclosure;

FIG. 24 is a block diagram showing another example of a point cloud coding system configured to implement embodiments of the present disclosure;

FIG. 25 is a block diagram illustrating an example of an encoding apparatus or a decoding apparatus;

FIG. 26 is a block diagram illustrating another example of an encoding apparatus or a decoding apparatus.

### DETAILED DESCRIPTION

In the following description, reference is made to the accompanying figures, which form part of the disclosure, and which show, by way of illustration, specific aspects of embodiments of the present disclosure or specific aspects in which embodiments of the present disclosure may be used. It is understood that embodiments of the present disclosure may be used in other aspects and comprise structural or logical changes not depicted in the figures. The following detailed description, therefore, is not to be taken in a limiting sense, and the scope of the invention is defined by the appended claims.

For instance, it is understood that a disclosure in connection with a described method may also hold true for a corresponding device or system configured to perform the method and vice versa. For example, if one or a plurality of specific method steps is described, a corresponding device may include one or a plurality of units, e.g. functional units, to perform the described one or plurality of method steps (e.g. one unit performing the one or plurality of steps, or a plurality of units each performing one or more of the plurality of steps), even if such one or more units are not explicitly described or illustrated in the figures. On the other hand, for example, if a specific apparatus is described based on one or a plurality of units, e.g. functional units, a corresponding method may include one step to perform the functionality of the one or plurality of units (e.g. one step performing the functionality of the one or plurality of units, or a plurality of steps each performing the functionality of one or more of the plurality of units), even if such one or plurality of steps are not explicitly described or illustrated in the figures. Further, it is understood that the features of the various exemplary embodiments and/or aspects described herein may be combined with each other, unless specifically noted otherwise.

### Three-Dimensional Point Cloud Data

There is a wide range of applications of three-dimensional point cloud data. The Motion Picture Experts Group (MPEG) point cloud compression (PCC) standardization activity has generated three categories of point cloud test data: static (many details, millions to billions of points, colors), dynamic (less point locations, with temporal information), and dynamically acquired (millions to billions of points, colors, surface normal and reflectance properties attributes).

The MPEG PCC standardization activity has chosen as test models for the three different categories targeted: LIDAR point cloud compression (L-PCC) for dynamically acquired data, Surface point cloud compression for (S-PCC) for static point cloud data, and Video-based point cloud compression (V-PCC) for dynamic content. These test models may be grouped into two classes: Video-based, equivalent to V-PCC, appropriate for point sets with a relatively uniform distribution of points, and Geometry-based (G-PCC), equivalent to the combination of L-PCC and S-PCC, appropriate for more sparse distributions.

There are many applications using point clouds as the preferred data capture format.

An example are virtual reality/augmented reality (VR/AR) applications. Dynamic point cloud sequences can provide the user with the capability to see moving content from any viewpoint: a feature that is also referred to as 6 Degrees of Freedom (6DoF). Such content is often used in virtual/augmented reality (VR/AR) applications. For example, in point cloud visualization applications using mobile devices were presented. Accordingly, by utilizing the available video decoder and GPU resources present in a mobile phone, V-PCC encoded point clouds may be decoded and reconstructed in real-time. Subsequently, when combined with an AR framework (e.g. ARCore, ARkit), the point cloud sequence can be overlaid on a real world through a mobile device.

Another exemplary application may be in the field of telecommunication. Because of high compression efficiency, V-PCC enables the transmission of a point cloud video over a band-limited network. It can thus be used for tele-presence applications. For example, a user wearing a head mount display device will be able to interact with the virtual world remotely by sending/receiving point clouds encoded with V-PCC.

For example, autonomous driving vehicles use point clouds to collect information about the surrounding environment to avoid collisions. Nowadays, to acquire three-dimensional information, multiple visual sensors are mounted on the vehicles. LIDAR sensor is one such example: it captures the surrounding environment as a time-varying sparse point cloud sequence. G-PCC can compress this sparse sequence and therefore help to improve the dataflow inside the vehicle with a light and efficient algorithm.

Furthermore, for a cultural heritage archive, an object may be scanned with a 3D sensor into a high-resolution static point cloud. Many academic/research projects generate high-quality point clouds of historical architecture or objects to preserve them and create digital copies for a virtual world. Laser range scanner or Structure from Motion (SfN) techniques may be employed in the content generation process. Additionally, G-PCC may be used to lossless compress the generated point clouds, reducing the storage requirements while preserving the accurate measurements.

### Tree Partitioning for Point Cloud Compression

Point clouds contain a set of high dimensional points, typically of three dimensions, each including three-dimensional position information and additional attributes such as color, reflectance, etc. Unlike two-dimensional image representations, point clouds are characterized by their irregular and sparse distribution across the three-dimensional space. Two major issues in point cloud compression (PCC) are geometry coding and attribute coding. Geometry coding is the compression of three-dimensional positions of a point set, and attribute coding is the compression of attribute values. In state-of-the-art PCC methods, geometry is generally compressed independently from attributes, while the attribute coding is based on the prior knowledge of the reconstructed geometry.

A three-dimensional space enclosed in a bounding box B, which includes a three-dimensional point-cloud, may be partitioned into sub-volumes. This partitioning may be described by a tree data structure. A hierarchical tree data structure can effectively describe sparse three-dimensional information. A so-called N-ary tree is a tree data structure in which each internal node has at most N children. A full N-ary tree is an N-ary tree where within each level, every node has either 0 or N children. Here, N is an integer larger than 1.

An octree is an exemplary full N-ary tree in which each internal node has exactly N=8 children. Thus, each node subdivides the space into eight nodes. For each octree branch node, one bit is used to represent each child node. This configuration can be effectively represented by one byte, which is considered as the occupancy node based encoding.

Other exemplary N-ary tree structures are binary trees (N=2) and quadtrees (N=4).

First, the bounding box is not restricted to be a cube; instead it can be an arbitrary-size rectangular cuboid to better fit for the shape of the three-dimensional scene or objects. In an exemplary implementation, the size of the bounding box may be represented as a power of two, i.e., (2^{dx}, 2^{dy}, 2^{dz}) Note that dx, dy, dz are not necessarily assumed to be equal, they may be signaled separately in the slice header of the bitstream.

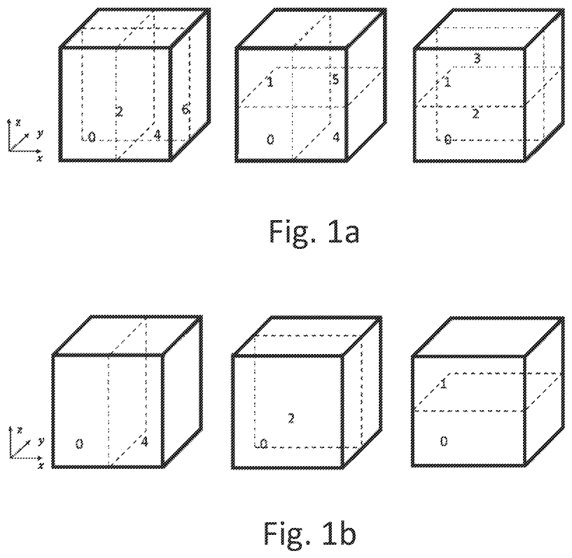

As the bounding box may not be a perfect cube (square cuboid), in some cases the node may not be (or unable to be) partitioned along all directions. If a partitioning is performed in all three directions, it is a typical octree partition. If performed in two directions out of three, it is a quadtree partition in three dimensions. If the partitioning is performed in one direction only, it is a binary tree partition in three dimensions. Examples of a quadtree partitioning of a cube are shown in FIG. 1a and examples of a binary tree partitioning of a cube are shown in FIG. 1b. When pre-defined conditions are met, quadtree and binary tree partitioning may be performed implicitly. “Implicitly” implies that no additional signaling bits may be needed to indicate that a quadtree or binary tree partitioning, instead of an octree partitioning, is used. Determining the type and direction of the partitioning may be based on pre-defined conditions.

More precisely, bitstream can be saved from an implicit geometry partitioning when signaling the occupancy code of each node. A quadtree partition requires four bits to represent the occupancy status of four sub-nodes, while a binary tree partition requires two bits. Note that quadtree and binary tree partitions can be implemented in the same structure as the octree partition.

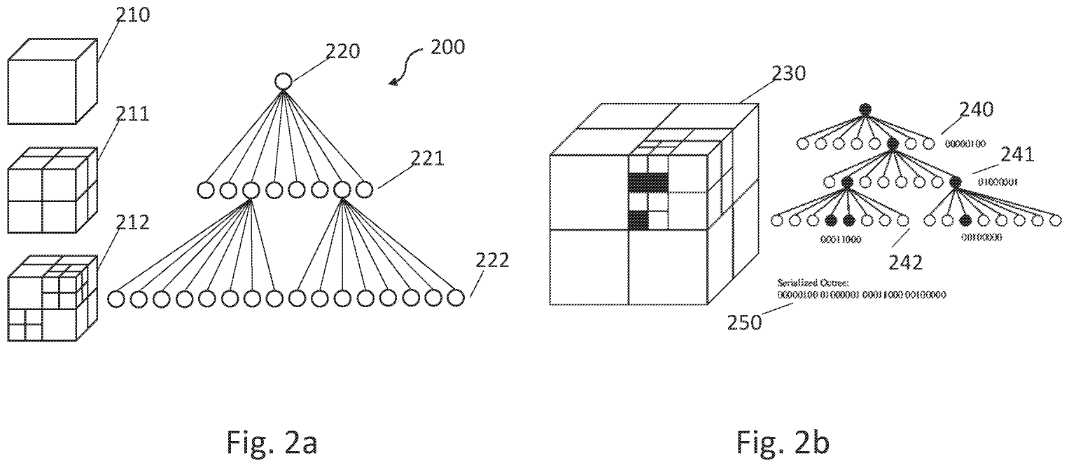

An octree partitioning is exemplarily shown in FIG. 2a for a cubic bounding box 210. The bounding box 210 is represented by the root node 220. Given a point cloud, the corners of the cubic bounding box are set to the maximum and minimum values of the input point cloud-aligned bounding box. The cube is subdivided into octants 211, each octant being represented by a node 221 within the tree 200. If a node contains more points than a threshold, it is recursively subdivided into further eight nodes 222 corresponding to a finer division 212. This is shown exemplarily for the third and the seventh octant in FIG. 2a. Next, partitioning and allocations are repeated until all leaf nodes contain no more than one point. A leaf node or leaf is anode without children nodes. Finally, an octree structure, in which each point is settled, is constructed.

For each node, associated information regarding the occupancy of the children is available. This is shown exemplarily in FIG. 2b. The cube 230 is subdivided into octants. Three sub-volumes include one three-dimensional point, respectively. The octree corresponding to this exemplary configuration and the occupancy codes for each layer are shown. White nodes represent unoccupied nodes and black nodes represent occupied nodes. An empty node is represented by a “0” and an occupied node is represented by a “1” in an occupancy code.

The occupancy of the octree may be given in serialized form, e.g. starting from the uppermost layer (children nodes of the root node). In the first layer 240 one node is occupied. This is represented by the occupancy code “00000100” of the root node. In the next layer, two nodes are occupied. The second layer 241 is represented by the occupancy code “11000000” of the single occupied node in the first layer. Each octant represented by the two occupied nodes in the second layer is further subdivided, resulting in a third layer 242 in the octree representation. Said third layer is represented by the occupancy code “10000000” of the first occupied node in the second layer 241 and the occupancy code “10001000” of the second occupied node in the second layer 241. Thus the exemplary octree is represented by a serialized occupancy code 250 “00000100 11000000 10000000 10001000”.

By traversing the tree in different orders and outputting each occupied code encountered, the generated bit stream can be further encoded by an entropy encoding method such as, for example, an arithmetic encoder. In this way, the distribution of spatial points can be efficiently coded. In an exemplary coding scheme, the points in each eight-leaf node are replaced by the corresponding centroid, so that each leaf contains only a single point. The decomposition level determines the accuracy of the data quantification and therefore may result in loss of the encoding.

From the partitioning, the octree stores point clouds by recursively partitioning the input space into equal octants and storing occupancy in a tree structure. Each intermediate node of the octree contains an 8-bit symbol to store the occupancy of its eight child nodes, with each bit corresponding to a specific child as explained above with reference to FIG. 2b.

As mentioned in the above example, each leaf contains a single point and stores additional information to represent the position of the point relative to the cell corner. The size of leaf information is adaptive and depends on the level. An octree with k levels can store k bits of precision by keeping the last k−i bits of each of the (x, y, z) coordinates for a child on the i-th level of the octree. The resolution increases as the number of levels in the octree increases. The advantage of such a representation is twofold: firstly, only non-empty cells are further subdivided and encoded, which makes the data structure adapt to different levels of sparsity; secondly, the occupancy symbol per node is a tight bit representation.

It is noted that the present disclosure is not limited to trees in which the leaf includes only a single point. It is possible to employ trees in which a leaf is a subspace (cuboid) which includes more than one points that may all be encoded rather than replaced by a centroid. Also, instead of the above mentioned centroid, another representative point may be selected to represent the points included in the space represented by the leaf.

Using a breadth-first or depth-first traversal, an octree can be serialized into two intermediate uncompressed bytestreams of occupancy codes. The original tree can be completely reconstructed from this stream. Serialization is a lossless scheme in the sense that occupancy information is exactly preserved.

The serialized occupancy bytestream of the octree can be further losslessly encoded into a shorter bit-stream through entropy coding. Entropy encoding is theoretically grounded in information theory. Specifically, an entropy model estimates the probability of occurrence of a given symbol; the probabilities can be adaptive given available context information. A key intuition behind entropy coding is that symbols that are predicted with higher probability can be encoded with fewer bits, achieving higher compression rates.

### Entropy Model

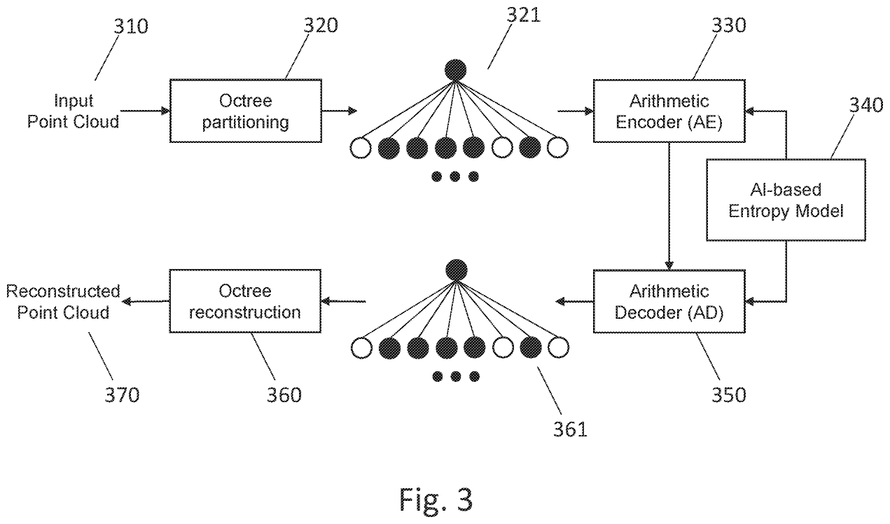

A point cloud of three-dimensional data points may be compressed using an entropy encoder. This is schematically shown in FIG. 3. The input point cloud 310 may be partitioned into an N-ary tree 320, for example an octree 321. The representation of the N-ary tree, which may be a serialized occupancy code as described in the example above, may be entropy encoded. Such an entropy encoder is, for example, an arithmetic encoder 330. The entropy encoder uses an entropy model 340 to encode symbols into a bitstream. At the decoding side, the entropy decoder, which may be, for example an arithmetic decoder 350, uses also the entropy model to decode the symbol from the bitstream. The N-ary tree 361 may be reconstructed 361 from the decoded symbols. Thus, a reconstructed point cloud 370 is obtained.

Given the sequence of occupancy 8-bit symbols x=[x1, x2, . . . , xn], the goal of an entropy model is to find an estimated distribution q(x) such that it minimizes the cross-entropy with the actual distribution of the symbols p(x). According to Shannon's source coding theorem, the cross-entropy between q(x) and p(x) provides a tight lower bound on the bitrate achievable by arithmetic or range coding algorithms; the better q(x) approximates p(x), the lower the true bitrate.

Such an entropy model may be obtained using artificial intelligence (AI) based models, for example, by applying neural networks. An AI-based model is trained to minimize the cross-entropy loss between the model's predicted distribution q and the distribution of training data

Entropy model q(x) is the conditional probabilities of each individual occupancy symbol xi as follows:

$$q ( x ) = {\prod }_{i} {q}_{i} ( {x}_{i} \vert {x}_{subset ( i )} , {c}_{i} ; w )$$

where: x_{subset(i)}={x_{i,0}, x_{i,1}, . . . , x_{i,K-1}} is the subset of available neighboring nodes, K-number of neighbors, and w represents the weights from neural network parametrizing our entropy model. Neighboring nodes may be within a same level in the N-ary tree as a respective current node.

During arithmetic decoding of a given occupancy code on the decoder side, context information such as node depth, parent occupancy, and spatial locations of the current octant are already known. Here, ci is the context information that is available as prior knowledge during encoding/decoding of xᵢ, such as octant index, spatial location of the octant, level in the octree, parent occupancy, etc. Context information such as location information help to reduce entropy even further by capturing the prior structure of the scene. For instance, in the setting of using LiDAR in the self-driving scenario, an occupancy node 0.5 meters above the LiDAR sensor is unlikely to be occupied. More specifically, the location may a node's three-dimensional location encoded as a vector in R³; the octant may be its octant index encoded as an integer in {0, . . . , 7}; the level may be its depth in the octree encoded as an integer in {0, . . . , d}; and the parent may be its parent's binary 8-bit occupancy code.

Said context information may be incorporated into the probability model using artificial neural networks as explained below.

### Artificial Neural Networks

Artificial neural networks (ANNs) are computing systems inspired by the biological neural networks that constitute animal brains. Such systems “learn” to perform tasks by considering examples, generally without being programmed with task-specific rules. For example, in image recognition, they might learn to identify images that contain cats by analyzing example images that have been manually labeled as “cat” or “no cat” and using the results to identify cats in other images. They do this without any prior knowledge of cats, for example, that they have fur, tails, whiskers and cat-like faces. Instead, they automatically generate identifying characteristics from the examples that they process.

An ANN is based on a collection of connected units or nodes called artificial neurons, which loosely model the neurons in a biological brain. Each connection, like the synapses in a biological brain, can transmit a signal to other neurons. An artificial neuron that receives a signal then processes it and can signal neurons connected to it.

In ANN implementations, the “signal” at a connection is a real number, and the output of each neuron is computed by some non-linear function of the sum of its inputs. The connections are called edges. Neurons and edges typically have a weight that adjusts as learning proceeds. The weight increases or decreases the strength of the signal at a connection. Neurons may have a threshold such that a signal is sent only if the aggregate signal crosses that threshold. Typically, neurons are aggregated into layers. Different layers may perform different transformations on their inputs. Signals travel from the first layer (the input layer), to the last layer (the output layer), possibly after traversing the layers multiple times.

The original goal of the ANN approach was to solve problems in the same way that a human brain would. However, over time, attention moved to performing specific tasks, leading to deviations from biology. ANNs have been used on a variety of tasks, including computer vision, speech recognition, machine translation, social network filtering, playing board and video games, medical diagnosis, and even in activities that have traditionally been considered as reserved to humans, like painting.

Fully connected neural networks (FCNNs) are a type of artificial neural network where the architecture is such that all the nodes, or neurons, in one layer are connected to the neurons in the next layer. Neurons in a fully connected layer have connections to all activations in the previous layer, as seen in regular (non-convolutional) artificial neural networks. Their activations can thus be computed as an affine transformation, with matrix multiplication followed by a bias offset (vector addition of a learned or fixed bias term).

While this type of algorithm is commonly applied to some types of data, in practice this type of network has some issues in terms of image recognition and classification. Such networks are computationally intense and may be prone to overfitting. When such networks are also ‘deep’ (meaning there are many layers of nodes or neurons) they can be particularly hard for humans to understand.

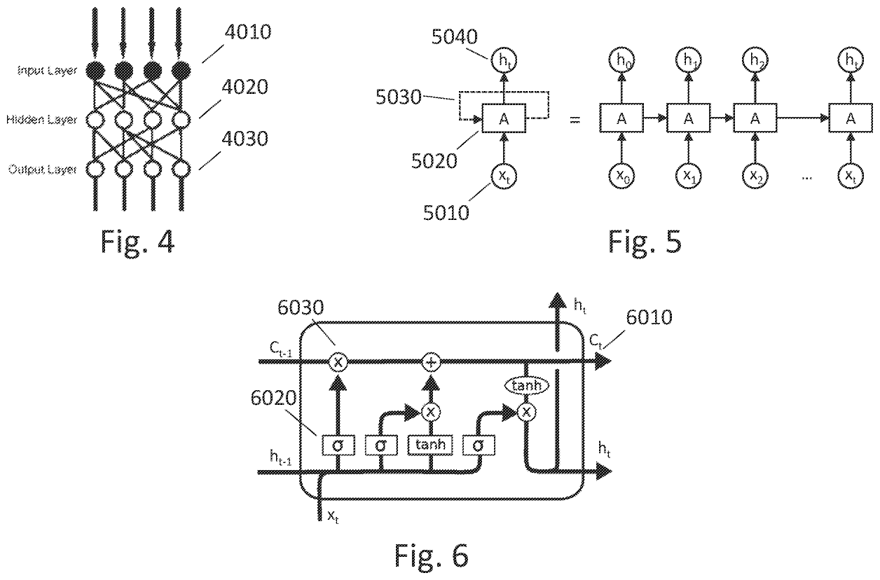

A Multi-Layer Perceptron (MLP) is an example for such a fully connected neural network. A MLP is a supplement of feed forward neural network. It consists of three types of layers—the input layer 4010, output layer 4030 and hidden layer 4020, as shown exemplarily in FIG. 4. The input layer receives the input signal to be processed. The required task such as prediction and classification is performed by the output layer. An arbitrary number of hidden layers that are placed in between the input and output layer are the true computational engine of the MLP. Similar to a feed forward network in a MLP the data flows in the forward direction from input to output layer. The neurons in the MLP are trained with the back-propagation learning algorithm. MLPs are designed to approximate any continuous function and can solve problems, which are not linearly separable. The major use cases of MLP are pattern classification, recognition, prediction and approximation.

A classification layer computes the cross-entropy loss for classification and weighted classification tasks with mutually exclusive classes. Usually classification layer is based on fully-connected network or multi-layer perceptron and softmax activation function for output. Classifier uses the features from the output of the previous layer to classify the object from image, for example.

The softmax function is a generalization of the logistic function to multiple dimensions. It may be used in multinomial logistic regression and may be used as the last activation function of a neural network to normalize the output of a network to a probability distribution over predicted output classes, based on Luce's choice axiom.

The softmax function takes as input a vector of real numbers, and normalizes it into a probability distribution consisting of K probabilities proportional to the exponentials of the input numbers. That is, prior to applying softmax, some vector components may be negative, or greater than one; and might not sum to 1; but after applying softmax, each component will be in the interval and the components will add up to 1. Thus, the components may be interpreted as probabilities. Furthermore, larger input components will correspond to larger probabilities.

A convolutional neural network (CNN) employs a mathematical operation called convolution. A convolution is a specialized kind of linear operation. Convolutional networks are neural networks that use a convolution operation in place of a general matrix multiplication in at least one of their layers.

A convolutional neural network consists of an input and an output layer, as well as multiple hidden layers. The hidden layers of a CNN typically consist of a series of convolutional layers that convolve with a multiplication or other dot product. The activation function may be a RELU layer, and may be subsequently followed by additional convolutions such as pooling layers, fully connected layers and normalization layers, referred to as hidden layers because their inputs and outputs are masked by the activation function and final convolution.

Though the layers are colloquially referred to as convolutions, this is only by convention. Mathematically, it is technically a sliding dot product or cross-correlation. This has significance for the indices in the matrix, in that it affects how weight is determined at a specific index point.

When programming a CNN, the input may be a tensor of dimension (number of images)×(image width)×(image height)×(image depth). Then after passing through a convolutional layer, the image becomes abstracted to a feature map, having dimensions (number of images)×(feature map width)×(feature map height)×(feature map channels). A convolutional layer within a neural network may have the following attributes: (i) convolutional kernels defined by a width and height (hyper-parameters), (ii) the number of input channels and output channels (hyper-parameter) and (iii) the depth of the convolution filter (the input channels) must be equal to the number channels (depth) of the input feature map.

The multilayer perceptron has been considered as providing a nonlinear mapping between an input vector and a corresponding output vector. Most of the work in this area has been devoted to obtaining this nonlinear mapping in a static setting. Many practical problems may be modeled by static models—for example, character recognition. On the other hand, many practical problems such as time series prediction, vision, speech, and motor control require dynamic modeling: the current output depends on previous inputs and outputs.

Recurrent neural networks (RNN) are a class of neural networks that is powerful for modeling sequence data such as time series or natural language. Recurrent networks are distinguished from feedforward networks by that feedback loop connected to their past decisions, ingesting their own outputs moment after moment as input. It is often said that recurrent networks have memory. Adding memory to neural networks has a purpose: There is information in the sequence itself, and recurrent nets use it to perform tasks.

A schematic illustration of a recurrent neural network is given in FIG. 5. In the exemplary diagram, a neural network A 5020, looks at some input xₜ 5010 and outputs a value hₜ 5040. A loop 5030 allows information to be passed from one step of the network to the next. The sequential information is preserved in the recurrent network's hidden state, which manages to span many time steps as it cascades forward to affect the processing of each new example. Recurrent neural networks have the form of a chain of repeating modules of neural network. In standard RNNs, said repeating module may have a very simple structure, such as a single tanh layer. It is finding correlations between events separated by many moments, and these correlations are called “long-term dependencies”, because an event downstream in time depends upon, and is a function of, one or more events that came before. One way to think about RNNs is this: they are a way to share weights over time.

Long Short-Term Memory (LSTM) networks are a type of recurrent neural network capable of learning order dependence in sequence prediction problems. This is a behavior required in complex problem domains like machine translation, speech recognition, and more. LSTMs also have the above mentioned chain like structure, but the repeating module may have a different structure.

An exemplary scheme of an LSTM repeating module is shown in FIG. 6. The key to LSTMs is the cell state 6010. The cell state runs straight down the entire chain, with only some minor linear interactions. Information may flow along the chain unchanged. The LSTM does have the ability to remove or add information to the cell state, carefully regulated by structures called gates. Gates may be composed out of a sigmoid neural net layer 6020 and a pointwise multiplication operation 6030.

LSTMs contain information outside the normal flow of the recurrent network in the gated cell. The cell makes decisions about what to store, and when to allow reads, writes and erasures, via gates that open and close. These gates are analog, implemented with element-wise multiplication by sigmoids, which are all in the range of 0-1.

Analog has the advantage of those gates act on the signals they receive, and similar to the neural network's nodes, they block or pass on information based on its strength and import, which they filter with their own sets of weights. Those weights, like the weights that modulate input and hidden states, are adjusted via the recurrent networks learning process.

### Attention-Based Layers in Neural Networks

Attention mechanism was first proposed in the natural language processing (NLP) field. In the context of neural networks, attention is a technique that mimics cognitive attention. The effect enhances the important parts of the input data and fades out the rest—the thought being that the network should devote more computing power on that small but important part of the data. This simple yet powerful concept has revolutionized the field, bringing out many breakthroughs in not only NLP tasks, but also recommendation, healthcare analytics, image processing, speech recognition, and so on.

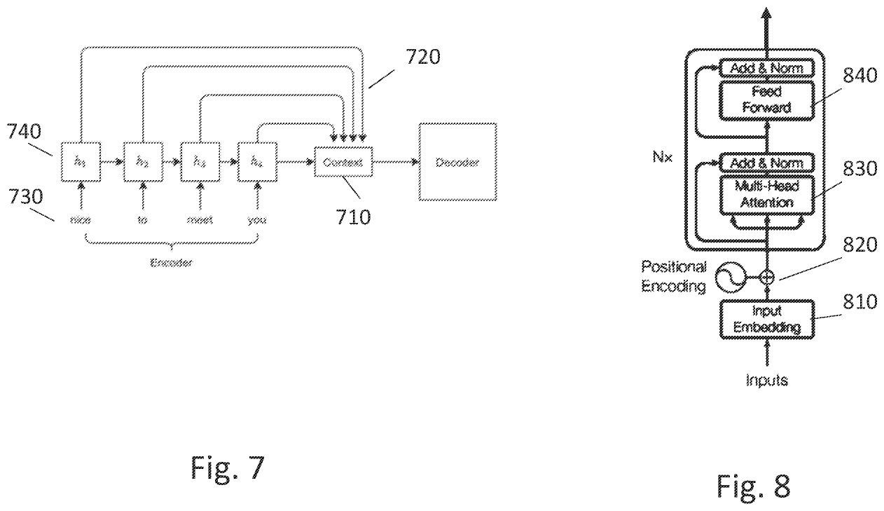

As shown in FIG. 7, instead of building a context vector 710 solely based on the encoder's last hidden state, the attention mechanism creates connections 720 between the entire input sequence 730 and the context vector 710. The weights of these connections 720 may be learned jointly with the rest of the model by training. During inference, the context vector 710 is computed as the weighted sum of encoder's hidden states 740 of all time steps.

Originally, attention is computed over the entire input sequence (global attention). Despite its simplicity, it may be computationally expensive. Using local attention may be a solution.

One exemplary implementation of the attention-mechanism is the so-called transformer model. In the transformer model, an input tensor is first fed to a neural network layer in order to extract features of the input tensor. Thereby a so-called embedding tensor 810 is obtained, which includes the latent space elements that are used as an input to a transformer. Positional encodings 820 may added to the embedding tensors. The positional encodings 820 enable a transformer to take into account a sequential order of the input sequence. These encodings may be learned or pre-defined tensors may represent the order of the sequence.

The positional information may be added by a special positional encoding function, usually in the form of sine and cosine functions of different frequencies:

$$P E ( i , j ) = \{ \begin{matrix}sin ( \frac{i}{1000 {0}^{\frac{2 j}{M}}} ) , i = odd \\ cos ( \frac{i}{1000 {0}^{\frac{2 j}{M}}} ) , i = even\end{matrix}$$

where i denotes position within the sequence, j denotes the embedding dimension to be encoded, M is the embedding dimension. Hence, j belongs to the interval [0, M].

When the positional encoding 820 is calculated, it is piece-wisely added to the embedded vectors 810. Then the input vectors are prepared to enter the encoder block of the transformer. The encoder block exemplarily shown in FIG. 8 consists of two consequential steps: multi-head attention 830 and linear transformation 840 with non-linear activation function applied to each position separately and identically. The role of the attention blocks here is similar to the recurrent cells, however, with less computational requirements.

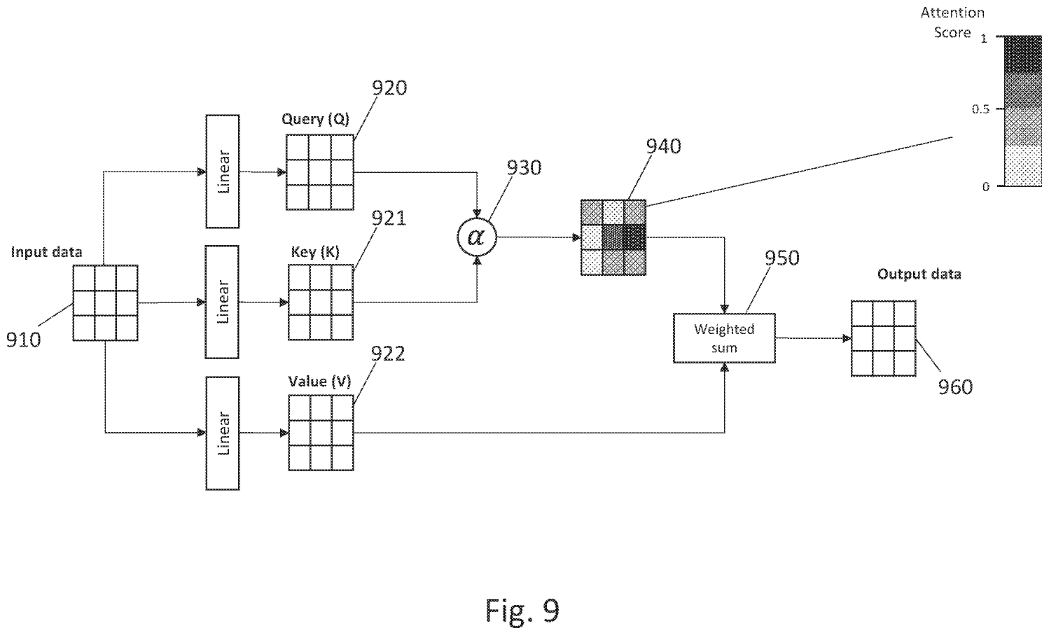

Self-Attention is a simplification of a generic attention mechanism, which consists of the queries Q 920, keys K 921 and values V 922. This is shown exemplarily in FIG. 9. The origin of such naming can be found in search engines, where a user's query is matched against internal engine's keys and the result is represented by several values. In case of a self-attention module, all three vectors come from the same sequence 910 and represent vectors with positional encoding built in. Moreover, this notation enables parallel attention execution, speeding up the whole system.

After combining the embedding vector with the positional encodings, three different representations namely Queries 920, Keys 921 and Values 922 are obtained by a feed-forward neural network layers. In order to calculate the attention, first an alignment 930 between Queries 920 and Keys 921 is calculated, and the softmax function is applied to obtain attention scores 940. Next, these scores are multiplied 950 with the Values 922 in a weighted sum, resulting in new vectors 960.

An attention mechanism uses dependent weights, which are named attention scores to linearly combine the inputs. Mathematically, given an input∈R^{N-1×M} a query Q E R^{N-1×M} to attend to the input X, the output of the attention layer is:

$$A t t n ( Q , X ) = A \cdot X = S ( Q , X ) \cdot X$$

where S: R^{N-1×M}×R^{N-1×M}→R^{N-1×N-1} is a matrix function for producing the attention weights A.

As a main result, the attention layer produces a one-row matrix Y∈R^{N-1×M} that contains a weighted combination from N−1 neighboring embeddings from tree level.

In other words, an attention layer obtains a plurality of representations of an input sequence, for example the Keys, Queries and Values. To obtain a representation out of said plurality of representations, the input sequence is processed by a respective set of weights. This set of weights may be obtained in a training phase. These set of weights may be learned jointly with the remaining parts of a neural network including such an attention layer. During inference, the output is computed as the weighted sum of the processed input sequence.

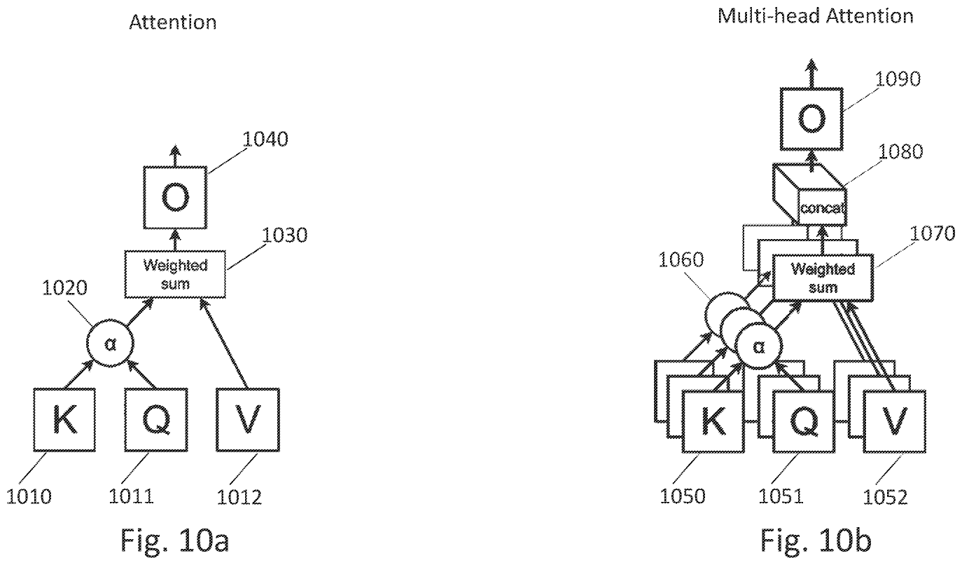

Multi-head attention may be seen as a parallel application of several attention functions on differently projected input vectors. A single attention function is illustrated in FIG. 10a and the parallel application in multi-head attention is shown in FIG. 10b. By doing more projections and attention computations, the model is enabled to have various perspectives of the same input sequence. It jointly attends to information from different angles, which is mathematically expressed via different linear subspaces.

The exemplary single attention function in FIG. 10a performs, as explained above, an alignment 1020 between the Keys 1010 and the Queries 1011, and obtains an output 1040 by applying a weighted sum 1030 to the attention score and the Values 1012. The exemplary multi-head attention in FIG. 10b performs an alignment 1060 for each pair of Keys 1050 and Queries 1051. Each pair may belong to a different linear subspace. For each obtained attention score and the respective Value 1052 a weighted sum 1070 is calculated. The results are concatenated 1080 to obtain an output 1090.

Scaled Dot-Product Attention is a slightly modified version of classical attention, where the scaling factor \sqrt{1/dk} is introduced in order to prevent the softmax function from giving values close to 1 for highly correlated vectors and values close to 0 for non-correlated vectors, making gradients more reasonable for back-propagation. The mathematical formula of Scaled Dot-Product Attention is:

$$Attention ( Q , K , V ) = softmax ( \frac{Q {K}^{T}}{√ dk} ) V$$

Multi-Head attention applies Scaled Dot-Product Attention mechanism in every attention head and then concatenates the results into one vector followed by a linear projection to the subspace of the initial dimension. The resulting algorithm of multi-head attention can be formalized as follows:

$$MultiHead ( Q , K , V ) = concat ( {head}_{1} , … , {head}_{h} ) W°$$

where headᵢ=Attention(QWᵢ^{Q}, KWᵢ^{K}, VWᵢ^{V}).

The next step after Multi-Head attention in the encoder block is a simple position-wise fully connected feed-forward network. There is a residual connection around each block, which is followed by a layer normalization. The residual connections help the network to keep track of data it looks at. Layer normalization plays an important role in reducing features variance.

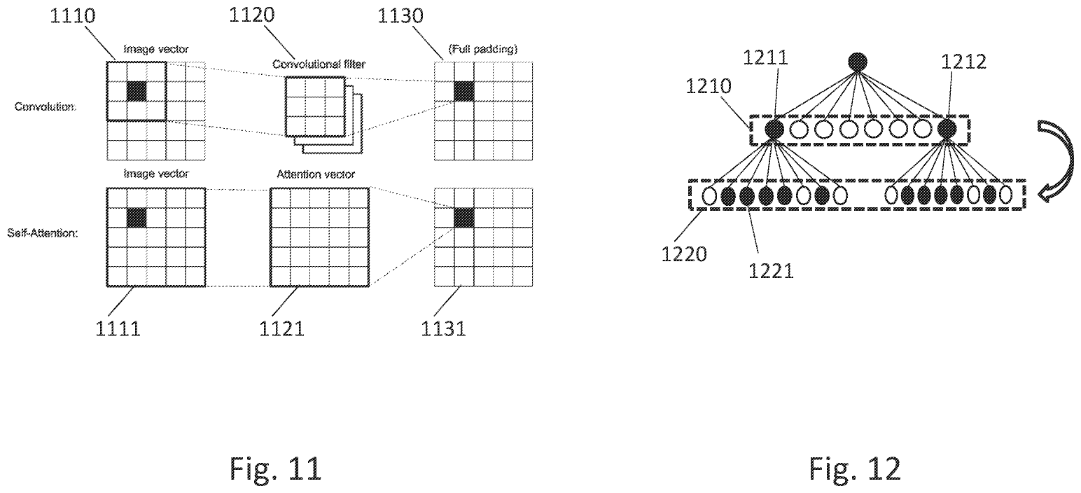

The transformer model has revolutionized the natural language processing domain. Additionally, it was concluded that self-attention models might outperform convolutional networks over two-dimensional image classification and recognition. This beneficial effect may be achieved because self-attention in the vision context is designed to explicitly learn the relationship between one pixel and all other positions, even regions far apart, it can easily capture global dependencies. FIG. 11 shows exemplarily the difference between a convolution layer and an attention layer. The convolutional operator and the self-attention have a different receptive field. The convolution operator 1120 is applied to a part of the image vector 1110 to obtain the output 1130. In this example, the attention vector 1121 is of the same size as the image vector 1111. Thus, the output 1131 receives an attention-weighted contribution from the full image vector.

Since three-dimensional point cloud data is an irregular set of points with positional attributes, self-attention models are suitable for data processing to extract internal dependencies for better entropy modeling.

### Attention-Based Entropy Modelling

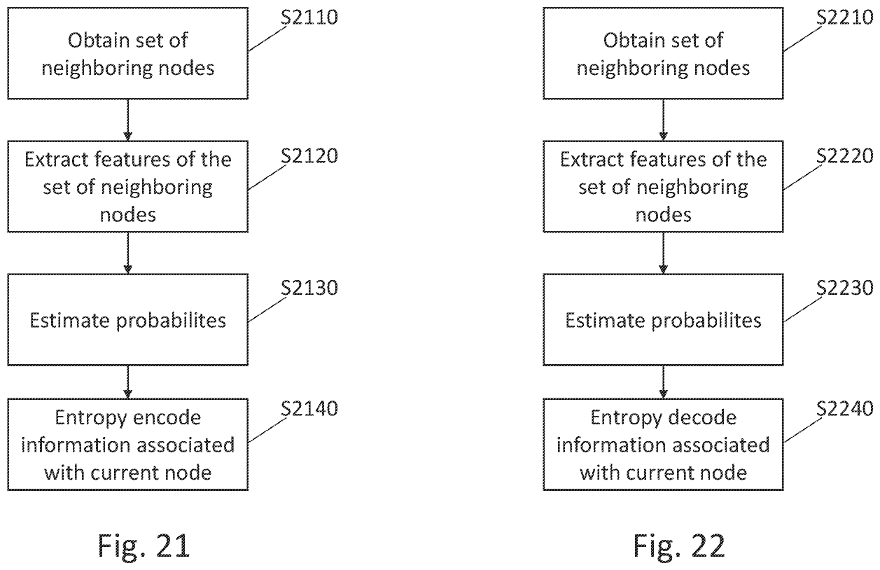

An entropy encoder as exemplarily explained above with reference to FIG. 3 uses an entropy model 340 to encode symbols into a bitstream. To encode a current node in an N-ary tree structure as explained above with references to FIGS. 1 and 2, which represents a three-dimensional point cloud, a set of neighboring nodes of the current node is obtained S2110. An exemplary flowchart of the encoding method is shown in FIG. 21. Said neighboring nodes may be within a same level in the N-ary tree as the current node. FIG. 12 exemplarily depicts such same layers 1210 or 1220 in an octree. For example, for a current node 1211 in the first layer 1210, the seven remaining nodes in said first layer may form a set of neighboring nodes. For a current node 1221 in the second layer 1220 of this exemplary octree, there are 15 neighboring nodes in the same layer.

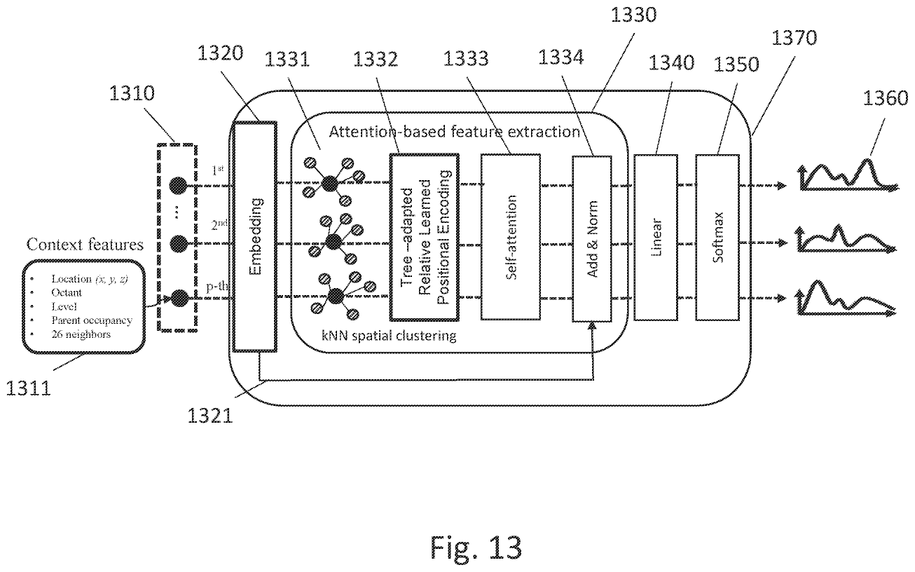

Features of the set of neighboring nodes are extracted S2120 by applying a neural network 1370. An exemplary scheme of the neural network 1370 is provided in FIG. 13. Context features 1311 of the nodes in the set of neighboring nodes 1310 may be provided as input to the neural network. Said neural network includes an attention layer 1333. Exemplary implementations of such an attention layer are described in the section Attention-based layers in neural networks above with reference to FIGS. 7 to 11. In other words, the set of neighboring nodes provides an input to a neural network. Said set is processed by the one or more layers of the neural network, wherein at least one layer is an attention layer. The attention layer produces a matrix, which contains a weighted combination of features of neighboring nodes, e.g. from a tree level.

There is information associated with each node of the N-ary tree. Such information may include for example an occupancy code of the respective node. In the exemplary octree shown in FIG. 12 white nodes represent empty nodes and black nodes represent occupied nodes. An empty node is represented by a “0” and an occupied node is represented by a “1” in an occupancy code. Thus, the exemplary node 1212 has an associated occupancy code 01111010.

For information associated with the current node, probabilities 1360 are estimated S2130 based on the extracted features. The information associated with the current node is entropy encoded S2140 based on the estimated probabilities. Said information associated with the current node may be represented by an information symbol. The information symbol may represent the occupancy code of the respective current node. Said symbol may be entropy encoded based on estimated probabilities corresponding to the information symbols.

In a first exemplary embodiment, the extraction of features may use relative positional information of a neighboring node and the current node. The relative positional information may be obtained for each neighboring node within the set of neighboring nodes. Examples for spatially neighboring subvolumes corresponding to spatially neighboring nodes are shown in FIG. 20.

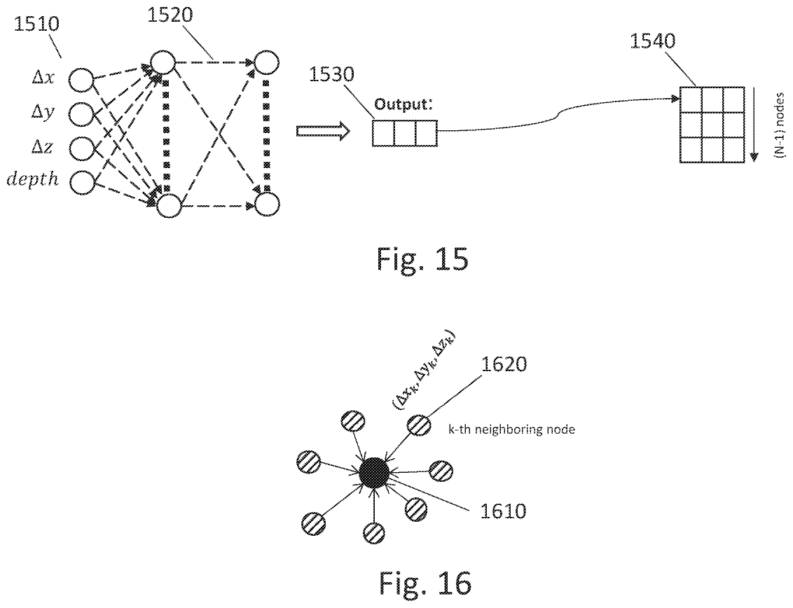

The relative positional information 1510 of the first exemplary embodiment may be processed by the neural network 1370 by applying a first neural subnetwork 1520. Said subnetwork may be applied for each neighboring node within the set of neighboring nodes. An exemplary scheme for one node is shown in FIG. 15. The relative positional information 1510 may include differences in the three-dimensional positions of the nodes within the three-dimensional point cloud. As for example shown in FIG. 16, the relative positional information 1510 of a k-th node 1620 may include the three spatial differences (Δxₖ, Δyₖ, Δzₖ) with respect to the current node 1610. For each neighboring node, an output vector 1530 may be obtained. A combined output 1540 may include the processed relative positional information for the (P−1) neighboring nodes in an exemplary set of P nodes.

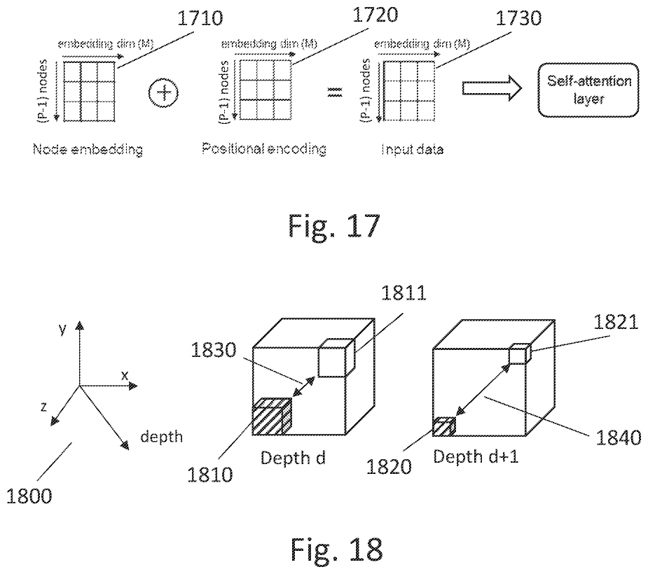

The obtained output of the first neural subnetwork may be provided as an input to the attention layer. This is exemplarily discussed in section Attention-based layers in neural networks. The providing as an input to the attention layer may include additional operations such as a summation or a concatenation, or the like. This is exemplarily shown in FIG. 17, where the positional encoding 1720 is added elementwise for the (P−1) neighboring nodes and the M dimensions of the embedding to a node embedding 1710. The exemplary combined tensor 1730 is provided as input to the attention layer.

Positional encoding helps the neural network utilize positional features before an attentional layer in the network. During the layer-by-layer octree partitioning, for given node the neighboring nodes within the level of the tree and their respective context features are available. In this case, attention layer may extract more information from features of neighboring nodes for better entropy modelling.

The input to the first neural subnetwork 1520 in the first exemplary embodiment may include a level of the current node within the N-ary tree. Said level indicates the depth within the N-ary tree. This is exemplarily shown in FIG. 18. For instance, the depth is provided as additional information. Using depth as an additional input, this creates a 4-dimensional metric space 1800. At a depth d the distance 1830 between two sub-volumes 1810 and 1811 corresponding to two nodes at level d is smaller than the distance 1840 between two sub-volumes 1820 and 1821 corresponding to two nodes at level d+1, which share partially the same three-dimensional space as the sub-volumes at level d. Since, position and depth are known for each node from the constructed tree, a MLP may calculate relative positional encodings. The positional network of FIG. 15 extracts a learned pair-wise distance between current and a respective neighboring node. The so-called tree-adapted relative learned positional encoding 1332 may be an additional step in the attention-based feature extraction 1330 as shown in FIG. 13. The first neural subnetwork 1520 may be a multilayer perceptron, which is explained above with reference to FIG. 4. In the case of applying a multilayer perceptron, the spatial differential distances are processed by a linear layer.

In a second exemplary embodiment, the neural network 1370 may comprise a second neural subnetwork 1320 to extract features of the set of neighboring nodes. Said features may be independent deep features (also called embeddings) for each node. Therefore, said second neural subnetwork may include a so-called embedding layer 1320 to extract contextual embedding in high-dimensional real-valued vector space. The second neural subnetwork 1320 may be a multilayer perceptron, which is explained above with reference to FIG. 4. A MLP may receive a signal in input layer, and may output a high-dimensional representation of the input. In between the input layer and the output layer, a predetermined number of hidden layers are the basic computational engine of the MLP:

$${h}_{i} = MLP ( {c}_{i} )$$

where hᵢ represents a high-dimensional real-valued learned embedding for given node i. The output of the second neural subnetwork may be provided as an input to a subsequent layer within the neural network. Such a subsequent layer may be, for example, the attention layer. The output of the second neural subnetwork 1320 of the second exemplary embodiment may be combined with the output of the first neural subnetwork 1520 of the first exemplary embodiment by an operation such as a summation or a concatenation.

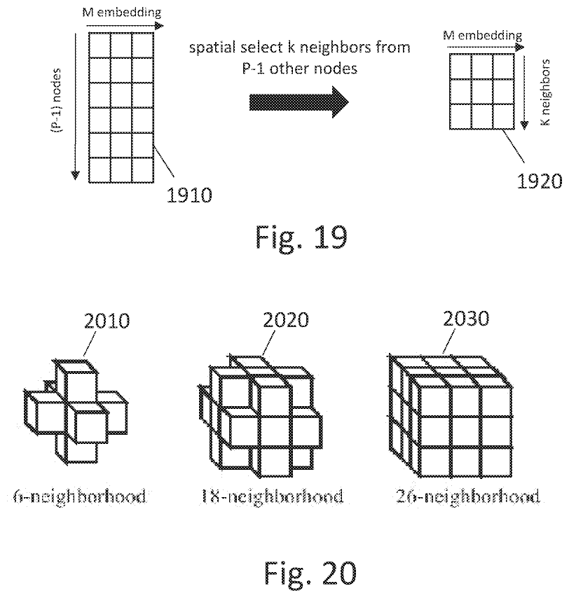

During the extraction of the features, a subset of neighboring nodes may be selected from the set of neighboring nodes in a third exemplary embodiment. Information corresponding to said subset may be provided to a subsequent layer within the neural network. FIG. 19 illustrates such an exemplary selection of a subset. In this example, an intermediate tensor 1910 has dimensions (P−1)×M, where (P−1) corresponds to the (P−1) neighboring nodes and M corresponds to the dimension of the context embedding for each node. From the (P−1) neighboring nodes, a subset of K nodes may be selected. A new intermediate tensor 1920 includes in this exemplary implementation the M-dimensional context embedding for the K neighboring nodes. Thus, said exemplary new intermediate tensor 1920 has a dimension K×M.

For example, the attention layer may not be applied to all neighboring nodes within the set. The attention layer may be applied to a selected subset of nodes. Thus, the size of the attention matrix is reduced as well as the computational complexity. An attention layer applied to all nodes within the set may be called global attention layer. An attention layer applied to a selected subset of nodes may be called local attention layer. Said local attention may reduce the input matrix size for the attention layer without significant loss of information.

The selecting of the subset of nodes in the third exemplary embodiment may be performed by a k-nearest neighbor algorithm. Said algorithm may select K neighbors. Said neighbors may be spatially neighboring points within the three-dimensional point cloud. The attention layer may be applied to the representation of the selected K neighboring nodes.

The input to the neural network may include context information of the set of neighboring nodes. Said neural network may incorporate any of the above-explained exemplary embodiments or any combination thereof. For each node, the context information may include the location of the respective node. The location may indicate the three-dimensional location (x, y, z) of the node. The three-dimensional location may lie in a range between (0,0,0) and (2^{d},2^{d},2^{d}), where d indicated the depth of the layer of the node. The context information may include information indicating a spatial position within the parent node. For an exemplary octree said information may indicate an octant within the parent node. The information indicating the octant may be an octant index, for example in a range [0, . . . , 7]. The context information may include information indicating the depth in the N-ary tree. The depth of a node in the N-ary tree may be given by a number in the range [0, . . . , d], where d may indicate the depth of the N-ary tree. The context information may include an occupancy code of the respective parent node of a current node. For an exemplary octree, the occupancy code of a parent node may be represented by an element in the range [0, . . . , 255]. The context information may include an occupancy pattern of a subset of nodes spatially neighboring said node. The neighboring nodes may be spatially neighboring the current node within the three-dimensional point cloud. FIG. 20 illustrates exemplary neighboring configurations. A first exemplary neighboring configuration 2010 includes 6 neighbors that share a common surface with the subvolume corresponding to the current node. A second exemplary configuration 2020 includes 18 neighbors, which share either a surface or an edge with the subvolume corresponding to the current node. A third exemplary configuration 2030 includes 26 neighbors, which share either a surface, an edge, or a vertex with the subvolume corresponding to the current node. An occupancy pattern may indicate the occupancy for each node within the subset of spatially neighboring nodes. Binary (1-bit) codes for each of the spatially neighboring nodes may be used to describe a local geometry configuration. For example, an occupancy pattern for a 26 neighbor configuration may be represented by a 26-bit binary code, wherein each bit indicates the occupancy of a respective neighboring node. The occupancy pattern may be extracted from the occupancy codes of the respective parent nodes of the spatially neighboring nodes. The context information may include one or more of the above-explained location of said node, octant information, depth in the N-ary tree, occupancy code of a respective parent node, or an occupancy pattern of a subset of nodes.

The attention layer 1333 in the neural network 1370 may be a self-attention layer. The self-attention layer is explained above with reference to FIG. 9, where the Queries 920, Keys 921 and Values 922 arise from a same input sequence 910. The Queries 920, Keys 921 and Values 922 are used extract internal dependencies and find correlations between nodes across a tree level.

The attention layer 1333 in the neural network 1370 may be a multi-head attention layer. A multi-head attention layer is explained above with reference to FIG. 10b. Multi-head attention applies of several attention functions on differently projected input vectors in parallel.

In a fourth exemplary embodiment, the neural network 1370 may include a third neural subnetwork 1340, which may perform the estimation of probabilities 1360 of information associated with the current node based on the extracted features as an output of the attention layer. The third subnetwork may be a multilayer perceptron. Such a MLP may generate an output vector, which fuses aggregated feature information.

The third neural subnetwork of the fourth exemplary embodiment may apply a softmax layer 1350 and obtain the estimated probabilities 1360 as an output of the softmax layer 1350. As explained above, the softmax function is a generalization of the logistic function to multiple dimensions. It may be used as the last activation function of a neural network to normalize the output of a network to a probability distribution.

The third neural subnetwork may perform the estimating of probabilities of information associated with the current node based on the context embedding related to the current node. The context embedding may be combined with the output of the attention-layer 1333. Said combination may be performed by adding the context embedding and the output of the attention-layer and by applying a norm. In other words, there may be a residual connection 1321 from the embedding layer to the output of the attention layer.

During the training, the neural network may suffer from vanishing gradient problems. This may be solved by a bypass of propagation with such a residual connection. Said residual connection 1321 combines an independent contextual embedding and aggregated neighboring information for better prediction.

The full entropy model may be trained end-to-end with the summarized cross-entropy loss, which is computed over all nodes of octree:

$${L}_{e n t r o p y} = - {\sum }_{i} {\sum }_{j} {y}_{i , j} log ( {q}_{i , j} )$$

where yᵢ is the one-hot encoding of the ground-truth symbol at non-leaf node i, and q_{i,j} is the predicted probability of symbol's occurrence at node i.

It is understood that the features of the various exemplary embodiments and/or aspects described herein may be combined with each other.

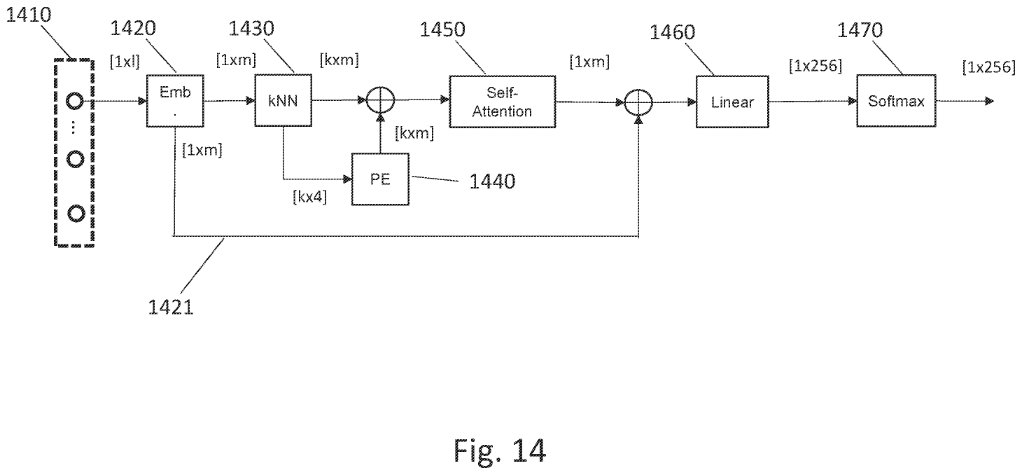

A possible implementation for the neural network 1370 is shown in an exemplary scheme in FIG. 14. This exemplary scheme depicts the processing of a single node out of a set of P nodes 1410. The current node may be described by l dimensions of context features, resulting in a [1×l]-input to the embedding layer 1420. The processing by the embedding layer may result in a m-dimensional context embedding for the current node. A subset of k nodes 1430 may be selected. A positional encoding 1440 is performed for the selected subset of nodes using, for example, the spatial distance (Δx, Δy, Δz) and the depth in the N-ary tree, which leads to a [k×4]-input to the positional encoding subnetwork. The [k×m]-output of the positional encoding may be added elementwise to the context embedding of the subset of k nodes. The subsequent attention layer 1450 receives in this example a [k×m]-input and obtains a [1×m]-output for the current node. The context embedding of the current node may be added to the output of the attention layer, indicated by the residual connection 1421 in FIG. 14. The processing may include a further neural subnetwork 1460, which obtains a value for each of the 256 possible symbols in this example. Said 256 symbols may correspond to occupancy codes of a current node in an octree. A final softmax layer 1470 may map the values obtained for each of the symbols to a probability distribution.

The obtaining of an entropy model using an attention layer for the decoding is similar to the estimating of probabilities during the encoding. Due to the representation of the data of the three-dimensional point cloud in an N-ary tree, for example an octree as in FIG. 12, the context information is available for all neighboring nodes within a same layer 1210 in the N-ary tree as a current node 1211.

To decode a current node in an N-ary tree structure, which represents a three-dimensional point cloud, as explained above with references to FIGS. 1 and 2, a set of neighboring nodes of the current node is obtained S2210. An exemplary flowchart of the encoding method is shown in FIG. 22. Said neighboring nodes may be within a same level in the N-ary tree as the current node. FIG. 12 exemplarily depicts such same layers 1210 or 1220 in an octree.

Features of the set of neighboring nodes are extracted S2220 by applying a neural network 1370. An exemplary scheme of the neural network, which may be used for encoding and decoding, is provided in FIG. 13, which is explained above in detail for the encoding method. Context features 1311 of the nodes in the set of neighboring nodes 1310 may be provided as input to the neural network. Said neural network includes an attention layer 1333. In other words, the set of neighboring nodes 1310 provides an input to a neural network. Said set is processed by the one or more layers of the neural network, wherein at least one layer is an attention layer.

An exemplary implementation of the attention layer 1333 in the neural network 1370 is a self-attention layer. The self-attention layer is explained above with reference to FIG. 9. The attention layer 1333 in the neural network may be a multi-head attention layer, which applies a plurality of attention or self-attention layers in parallel and which is explained above with reference to FIG. 10b.

For information associated with the current node, probabilities 1360 are estimated S2230 based on the extracted features. The information associated with the current node, for example an indication of an occupancy code, is entropy decoded S2240 based on the estimated probabilities. Said information associated with the current node may be represented by an information symbol. The information symbol may represent the occupancy code of the respective current node. Said symbol may be entropy decoded based on estimated probabilities corresponding to the information symbols.

Corresponding to the encoding side, the extraction of features may use relative positional information of a neighboring node and the current node. The relative positional information may be obtained for each neighboring node within the set of neighboring nodes. The relative positional information 1510 may be processed by the neural network 1370 by applying a first neural subnetwork 1520. This is explained above in detail with reference to FIG. 15. Said subnetwork may be applied for each neighboring node within the set of neighboring nodes. The obtained output of the first neural subnetwork may be provided as an input to the attention layer. The input to the first neural subnetwork may include a level of the current node within the N-ary tree. By applying positional encoding, the attention layer may extract more information from features of neighboring nodes for better entropy modelling. Analogously to the encoding side, first neural subnetwork 1520 may be a multilayer perceptron.

The neural network 1370 may comprise a second neural subnetwork to extract features of the set of neighboring nodes. This explained in detail for the encoding side and works analogously at the decoding side. The second neural subnetwork may be a multilayer perceptron. A subset of neighboring nodes may be selected from the set of neighboring during the extraction of the features. Information corresponding to said subset may be provided to a subsequent layer within the neural network, which is discussed above with reference to FIG. 19. The selecting of the subset of nodes in the third exemplary embodiment may be performed by a k-nearest neighbor algorithm.

Analogously to the encoding side, the input to the neural network includes context information of the set of neighboring nodes, the context information for a node including one or more of location of said node, octant information, depth in the N-ary tree, occupancy code of a respective parent node, and/or an occupancy pattern of a subset of nodes spatially neighboring said node.

Corresponding to the encoding side, the neural network 1370 may include a third neural subnetwork 1340, which may perform the estimation of probabilities 1360 of information associated with the current node based on the extracted features as an output of the attention layer. The third subnetwork may be a multilayer perceptron. A softmax layer 1350 may be applied within the third neural subnetwork and obtain the estimated probabilities 1360 as an output of the softmax layer 1350. The third neural subnetwork 1340 may perform the estimating of probabilities of information associated with the current node based on the context embedding related to the current node, for example by a residual connection 1321.

### Implementations in Hardware and Software

Some further implementations in hardware and software are described in the following.

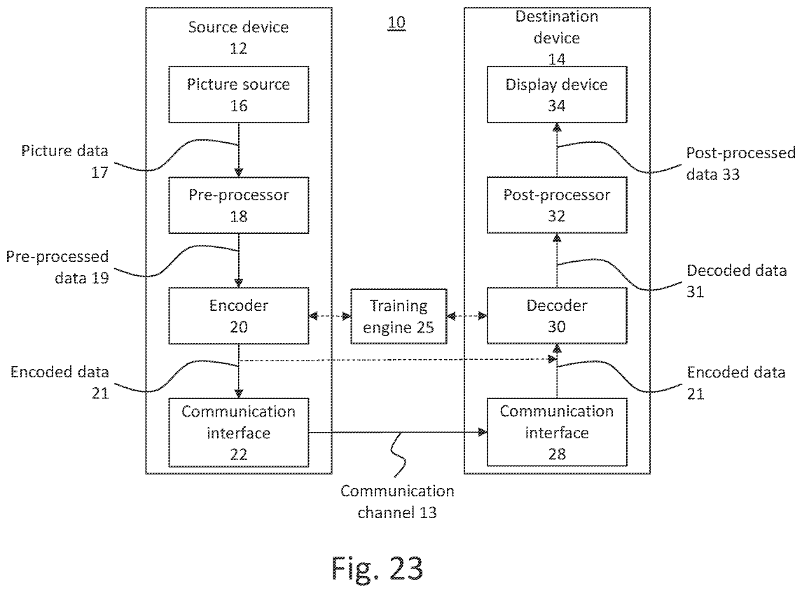

Any of the encoding devices described with references to FIGS. 23-26 may provide means in order to carry out entropy encoding data of a three-dimensional point cloud. A processing circuitry within any of these exemplary devices is configured to perform the encoding method. The method as described above comprises for a current node in an N-ary tree-structure representing the three-dimensional point cloud, obtaining a set of neighboring nodes of the current node, extracting features of the set of said neighboring nodes by applying a neural network including an attention layer, estimating probabilities of information associated with the current node based on the extracted features, and entropy encoding the information associated with the current node based on the estimated probabilities.

The decoding devices in any of FIGS. 14-17, may contain a processing circuitry, which is adapted to perform the decoding method. The method as described above comprises for a current node in an N-ary tree-structure representing the three-dimensional point cloud, obtaining a set of neighboring nodes of the current node, extracting features of the set of said neighboring nodes by applying a neural network including an attention layer, estimating probabilities of information associated with the current node based on the extracted features, and entropy decoding the information associated with the current node based on the estimated probabilities.

Summarizing, methods and apparatuses are described for entropy encoding and decoding data of a three-dimensional point cloud, which includes for a current node in an N-ary tree-structure representing the three-dimensional point cloud, extracting features of a set of said neighboring nodes of the current node by applying a neural network including an attention layer. Probabilities of information associated with the current node is estimated based on the extracted features. The information is entropy encoded based on the estimated probabilities.

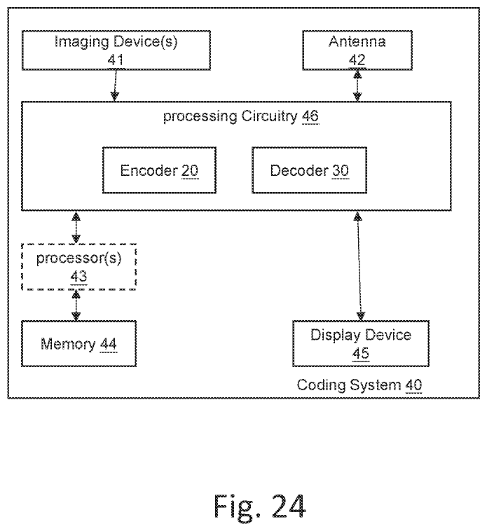

In the following embodiments of a coding system 10, a encoder 20 and a decoder 30 are described based on FIGS. 23 and 24.

FIG. 23 is a schematic block diagram illustrating an example coding system 10 that may utilize techniques of this present application. The encoder 20 and the decoder 30 of the coding system 10 represent examples of devices that may be configured to perform techniques in accordance with various examples described in the present application.

As shown in FIG. 23, the coding system 10 comprises a source device 12 configured to provide encoded picture data 21 e.g. to a destination device 14 for decoding the encoded picture data 13.

The source device 12 comprises an encoder 20, and may additionally, i.e. optionally, comprise a picture source 16, a pre-processor (or pre-processing unit) 18 and a communication interface or communication unit 22.

The picture source 16 may comprise or be any kind of three-dimensional point cloud capturing device, for example a 3D sensor such as LiDAR for capturing real-world data, and/or any kind of a three-dimensional point cloud generating device, for example a computer-graphics processor for generating a computer three-dimensional point cloud, or any kind of other device for obtaining and/or providing a real-world data and/or any combination thereof. The picture source may be any kind of memory or storage storing any of the aforementioned pictures.

In distinction to the pre-processor 18 and the processing performed by the pre-processing unit 18, the data or picture data 17 may also be referred to as raw data or raw picture data 17.

Pre-processor 18 is configured to receive the (raw) data 17 and to perform pre-processing on the data 17 to obtain pre-processed data 19. Pre-processing performed by the pre-processor 18 may, e.g., quantization, filtering, build maps, implement Simultaneous Localization and Mapping (SLAM) algorithms. It can be understood that the pre-processing unit 18 may be optional component.

The encoder 20 is configured to receive the pre-processed data 19 and provide encoded data 21.

Communication interface 22 of the source device 12 may be configured to receive the encoded data 21 and to transmit the encoded data 21 (or any further processed version thereof) over communication channel 13 to another device, e.g. the destination device 14 or any other device, for storage or direct reconstruction.

The destination device 14 comprises a decoder 30, and may additionally, i.e. optionally, comprise a communication interface or communication unit 28, a post-processor 32 (or post-processing unit 32) and a display device 34.

The communication interface 28 of the destination device 14 is configured receive the encoded data 21 (or any further processed version thereof), e.g. directly from the source device 12 or from any other source, e.g. a storage device, e.g. an encoded data storage device, and provide the encoded data 21 to the decoder 30.

The communication interface 22 and the communication interface 28 may be configured to transmit or receive the encoded data 13 via a direct communication link between the source device 12 and the destination device 14, e.g. a direct wired or wireless connection, or via any kind of network, e.g. a wired or wireless network or any combination thereof, or any kind of private and public network, or any kind of combination thereof.

The communication interface 22 may be, e.g., configured to package the encoded data 21 into an appropriate format, e.g. packets, and/or process the encoded data using any kind of transmission encoding or processing for transmission over a communication link or communication network.

The communication interface 28, forming the counterpart of the communication interface 22, may be, e.g., configured to receive the transmitted data and process the transmission data using any kind of corresponding transmission decoding or processing and/or de-packaging to obtain the encoded data 21.

Both, communication interface 22 and communication interface 28 may be configured as unidirectional communication interfaces as indicated by the arrow for the communication channel 13 in FIG. 23 pointing from the source device 12 to the destination device 14, or bi-directional communication interfaces, and may be configured, e.g. to send and receive messages, e.g. to set up a connection, to acknowledge and exchange any other information related to the communication link and/or data transmission, e.g. encoded data transmission.

The decoder 30 is configured to receive the encoded data 21 and provide decoded data 31.

The post-processor 32 of destination device 14 is configured to post-process the decoded data 31 (also called reconstructed data) to obtain post-processed data 33. The post-processing performed by the post-processing unit 32 may comprise, e.g. quantization, filtering, build maps, implement SLAM algorithms, resampling, or any other processing, e.g. for preparing the decoded data 31 for display, e.g. by display device 34.

The display device 34 of the destination device 14 is configured to receive the post-processed data 33 for displaying the data, e.g. to a user. The display device 34 may be or comprise any kind of display for representing the reconstructed data, e.g. an integrated or external display or monitor. The displays may, e.g. comprise liquid crystal displays (LCD), organic light emitting diodes (OLED) displays, plasma displays, projectors, micro LED displays, liquid crystal on silicon (LCoS), digital light processor (DLP) or any kind of other display.

The coding system 10 further includes a training engine 25. The training engine 25 is configured to train the encoder 20 (or modules within the encoder 20) or the decoder 30 (or modules within the decoder 30) to process input data or generate a probability model for entropy encoding as discussed above.

Although FIG. 23 depicts the source device 12 and the destination device 14 as separate devices, embodiments of devices may also comprise both or both functionalities, the source device 12 or corresponding functionality and the destination device 14 or corresponding functionality. In such embodiments the source device 12 or corresponding functionality and the destination device 14 or corresponding functionality may be implemented using the same hardware and/or software or by separate hardware and/or software or any combination thereof.

As will be apparent for the skilled person based on the description, the existence and (exact) split of functionalities of the different units or functionalities within the source device 12 and/or destination device 14 as shown in FIG. 23 may vary depending on the actual device and application.

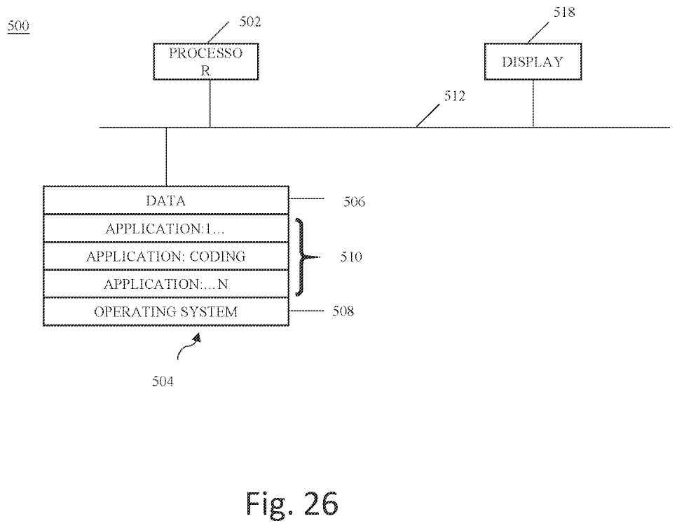

The encoder 20 or the decoder 30 or both encoder 20 and decoder 30 may be implemented via processing circuitry as shown in FIG. 24, such as one or more microprocessors, digital signal processors (DSPs), application-specific integrated circuits (ASICs), field-programmable gate arrays (FPGAs), discrete logic, hardware, coding dedicated or any combinations thereof. The encoder 20 may be implemented via processing circuitry 46 to embody the various modules as discussed with respect to the encoder part of FIG. 3 and/or any other encoder system or subsystem. The decoder 30 may be implemented via processing circuitry 46 to embody the various modules as discussed with respect to the decoder part of FIG. 3 and/or any other decoder system or subsystem. The processing circuitry may be configured to perform the various operations as discussed later. As shown in FIG. 26, if the techniques are implemented partially in software, a device may store instructions for the software in a suitable, non-transitory computer-readable storage medium and may execute the instructions in hardware using one or more processors to perform the techniques of this disclosure. Either of encoder 20 and decoder 30 may be integrated as part of a combined encoder/decoder (CODEC) in a single device, for example, as shown in FIG. 24.

Source device 12 and destination device 14 may comprise any of a wide range of devices, including any kind of handheld or stationary devices, e.g. notebook or laptop computers, mobile phones, smart phones, tablets or tablet computers, cameras, desktop computers, set-top boxes, televisions, display devices, digital media players, video gaming consoles, video streaming devices (such as content services servers or content delivery servers), broadcast receiver device, broadcast transmitter device, or the like and may use no or any kind of operating system. In some cases, the source device 12 and the destination device 14 may be equipped for wireless communication. Thus, the source device 12 and the destination device 14 may be wireless communication devices.

In some cases, coding system 10 illustrated in FIG. 23 is merely an example and the techniques of the present application may apply to coding settings (e.g., encoding or decoding) that do not necessarily include any data communication between the encoding and decoding devices. In other examples, data is retrieved from a local memory, streamed over a network, or the like. An encoding device may encode and store data to memory, and/or a decoding device may retrieve and decode data from memory. In some examples, the encoding and decoding is performed by devices that do not communicate with one another, but simply encode data to memory and/or retrieve and decode data from memory.

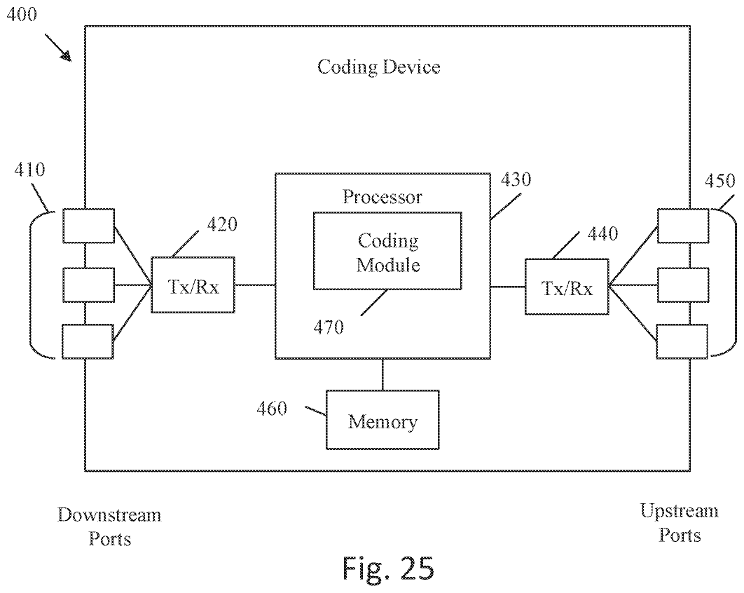

FIG. 25 is a schematic diagram of a coding device 400 according to an embodiment of the disclosure. The coding device 400 is suitable for implementing the disclosed embodiments as described herein. In an embodiment, the coding device 400 may be a decoder such as decoder 30 of FIG. 23 or an encoder such as encoder 20 of FIG. 23.

The coding device 400 comprises ingress ports 410 (or input ports 410) and receiver units (Rx) 420 for receiving data; a processor, logic unit, or central processing unit (CPU) 430 to process the data; transmitter units (Tx) 440 and egress ports 450 (or output ports 450) for transmitting the data; and a memory 460 for storing the data. The coding device 400 may also comprise optical-to-electrical (OE) components and electrical-to-optical (EO) components coupled to the ingress ports 410, the receiver units 420, the transmitter units 440, and the egress ports 450 for egress or ingress of optical or electrical signals.

The processor 430 is implemented by hardware and software. The processor 430 may be implemented as one or more CPU chips, cores (e.g., as a multi-core processor), FPGAs, ASICs, and DSPs. The processor 430 is in communication with the ingress ports 410, receiver units 420, transmitter units 440, egress ports 450, and memory 460. The processor 430 comprises a coding module 470. The coding module 470 implements the disclosed embodiments described above. For instance, the coding module 470 implements, processes, prepares, or provides the various coding operations. The inclusion of the coding module 470 therefore provides a substantial improvement to the functionality of the coding device 400 and effects a transformation of the coding device 400 to a different state. Alternatively, the coding module 470 is implemented as instructions stored in the memory 460 and executed by the processor 430.

The memory 460 may comprise one or more disks, tape drives, and solid-state drives and may be used as an over-flow data storage device, to store programs when such programs are selected for execution, and to store instructions and data that are read during program execution. The memory 460 may be, for example, volatile and/or non-volatile and may be a read-only memory (ROM), random access memory (RAM), ternary content-addressable memory (TCAM), and/or static random-access memory (SRAM).

FIG. 26 is a simplified block diagram of an apparatus 500 that may be used as either or both of the source device 12 and the destination device 14 from FIG. 23 according to an exemplary embodiment.

A processor 502 in the apparatus 500 can be a central processing unit. Alternatively, the processor 502 can be any other type of device, or multiple devices, capable of manipulating or processing information now-existing or hereafter developed. Although the disclosed implementations can be practiced with a single processor as shown, e.g., the processor 502, advantages in speed and efficiency can be achieved using more than one processor.

A memory 504 in the apparatus 500 can be a read only memory (ROM) device or a random access memory (RAM) device in an implementation. Any other suitable type of storage device can be used as the memory 504. The memory 504 can include code and data 506 that is accessed by the processor 502 using a bus 512. The memory 504 can further include an operating system 508 and application programs 510, the application programs 510 including at least one program that permits the processor 502 to perform the methods described here. For example, the application programs 510 can include applications 1 through N, which further include a coding application that performs the methods described herein, including the encoding and decoding using a neural network with a subset of partially updatable layers.

The apparatus 500 can also include one or more output devices, such as a display 518. The display 518 may be, in one example, a touch sensitive display that combines a display with a touch sensitive element that is operable to sense touch inputs. The display 518 can be coupled to the processor 502 via the bus 512.

Although depicted here as a single bus, the bus 512 of the apparatus 500 can be composed of multiple buses. Further, the secondary storage 514 can be directly coupled to the other components of the apparatus 500 or can be accessed via a network and can comprise a single integrated unit such as a memory card or multiple units such as multiple memory cards. The apparatus 500 can thus be implemented in a wide variety of configurations.

Embodiments, e.g. of the encoder 20 and the decoder 30, and functions described herein, e.g. with reference to the encoder 20 and the decoder 30, may be implemented in hardware, software, firmware, or any combination thereof. If implemented in software, the functions may be stored on a computer-readable medium or transmitted over communication media as one or more instructions or code and executed by a hardware-based processing unit. Computer-readable media may include computer-readable storage media, which corresponds to a tangible medium such as data storage media, or communication media including any medium that facilitates transfer of a computer program from one place to another, e.g., according to a communication protocol. In this manner, computer-readable media generally may correspond to (1) tangible computer-readable storage media, which is non-transitory, or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable medium.

By way of example, and not limiting, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transitory media, but are instead directed to non-transitory, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor,” as used herein may refer to any of the foregoing structure or any other structure suitable for implementation of the techniques described herein. In addition, in some aspects, the functionality described herein may be provided within dedicated hardware and/or software modules configured for encoding and decoding, or incorporated in a combined codec. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a codec hardware unit or provided by a collection of interoperative hardware units, including one or more processors as described above, in conjunction with suitable software and/or firmware.

What is claimed is:

1. A method for entropy encoding data of a three-dimensional point cloud applied to an electronic device, comprising:
for a current node in an N-ary tree-structure representing the three-dimensional point cloud:
obtaining a set of neighboring nodes of the current node;
extracting features of the set of the neighboring nodes by applying a neural network including an attention layer;
estimating probabilities of information associated with the current node based on the extracted features;
entropy encoding the information associated with the current node based on the estimated probabilities.

2. The method according to claim 1, wherein the extraction the features is based on relative positional information of a neighboring node and the current node within the three-dimensional point cloud as an input.

3. The method according to claim 2, wherein the extracting the features of the set of the neighboring nodes by applying the neural network comprises:
for each neighboring node within the set of neighboring nodes, applying a first neural subnetwork to the relative positional information of the respective neighboring node and the current node;
providing an obtained output for each neighboring node as an input to the attention layer, and
wherein an input to the first neural subnetwork includes a level of the current node within the N-ary tree.

4. The method according to claim 1, wherein the extracting the features of the set of the neighboring nodes by applying the neural network comprises applying a second neural subnetwork to output a context embedding into a subsequent layer within the neural network.

5. The method according to claim 1, wherein the extracting the features of the set of neighboring nodes includes selecting a subset of nodes from the set; and wherein information corresponding to nodes within the subset is provided as an input to a subsequent layer within the neural network, and
wherein the selecting the subset of nodes is performed by a k-nearest neighbor algorithm.

6. The method according to claim 1, wherein
the input to the neural network includes context information of the set of neighboring nodes, wherein the context information for a node includes one or more of
a location of the node,
octant information,
a depth in the N-ary tree,
an occupancy code of a respective parent node, and
an occupancy pattern of a subset of nodes spatially neighboring the node.

7. The method according to claim 1, wherein the attention layer in the neural network is a self-attention layer or wherein the attention layer in the neural network is a multi-head attention layer.

8. A method for entropy decoding data of a three-dimensional point cloud applied to an electronic device, the method comprising:
for a current node in an N-ary tree-structure representing the three-dimensional point cloud:
obtaining a set of neighboring nodes of the current node;
extracting features of the set of the neighboring nodes by applying a neural network including an attention layer;
estimating probabilities of information associated with the current node based on the extracted features;
entropy decoding the information associated with the current node based on the estimated probabilities.

9. The method according to claim 8, wherein the extraction the features of the set of the neighboring nodes is based on relative positional information of a neighboring node and the current node within the three-dimensional point cloud as an input.

10. The method according to claim 9, wherein the extracting the features of the set of the neighboring nodes by applying the neural network comprises:
for each neighboring node within the set of neighboring nodes, applying a first neural subnetwork to the relative positional information of the respective neighboring node and the current node;
providing the obtained output for each neighboring node as an input to the attention layer.

11. The method according to claim 10, wherein an input to the first neural subnetwork includes a level of the current node within the N-ary tree.

12. The method according to claim 8, wherein the extracting the features of the set of the neighboring nodes by applying the neural network comprises applying a second neural subnetwork to output a context embedding into a subsequent layer within the neural network.

13. The method according to claim 8, wherein the extracting the features of the set of neighboring nodes includes selecting a subset of nodes from the set; and
wherein information corresponding to nodes within the subset is provided as an input to a subsequent layer within the neural network, and wherein the selecting the subset of nodes is performed by a k-nearest neighbor algorithm.

14. The method according to claim 8, wherein
the input to the neural network includes context information of the set of neighboring nodes, wherein the context information for a node includes one or more of
a location of the node,
octant information,
a depth in the N-ary tree,
an occupancy code of a respective parent node, and
an occupancy pattern of a subset of nodes spatially neighboring the node.

15. The method according to claim 8, wherein the attention layer in the neural network is a self-attention layer.

16. The method according to claim 8, wherein the attention layer in the neural network is a multi-head attention layer.

17. The method according to claim 8, wherein the information associated with a node indicates the occupancy code of the node.

18. The method according to claim 8, wherein the neural network includes a third neural subnetwork, the third neural subnetwork performing the estimating of probabilities of information associated with the current node based on the extracted features as an output of the attention layer.

19. The method according to claim 18, wherein the third neural subnetwork comprises applying of a softmax layer and obtaining the estimated probabilities as an output of the softmax layer, or
wherein the third neural subnetwork performs the estimating of probabilities of information associated with the current node based on the context embedding related to the current node.

20. A non-transitory computer-readable medium including code instructions, which, upon being executed by one or more processors, cause the one or more processors to execute the method according to claim 1.

21. An apparatus for entropy encoding data of a three-dimensional point cloud, comprising:
a processing circuitry configured to:
for a current node in an N-ary tree-structure representing the three-dimensional point cloud:
obtain a set of neighboring nodes of the current node;
extract features of the set of the neighboring nodes by applying a neural network including an attention layer;
estimate probabilities of information associated with the current node based on the extracted features;
entropy encode the information associated with the current node based on the estimated probabilities.

22. An apparatus for entropy decoding data of a three-dimensional point cloud, comprising:
a processing circuitry configured to:
for a current node in an N-ary tree-structure representing the three-dimensional point cloud:
obtain a set of neighboring nodes of the current node;
extract features of the set of the neighboring nodes by applying a neural network including an attention layer;
estimate probabilities of information associated with the current node based on the extracted features;
entropy decode the information associated with the current node based on the estimated probabilities.
